(19) United States
(12) Patent Application Publication
(10) Pub. No.: US 2025/0329367 A1
(43) Pub. Date: Oct. 23, 2025

(54) MEMORY DEVICE

(71) Applicant: SAMSUNG ELECTRONICS CO., LTD., Suwon-si (KR)

(72) Inventors: Byoungkon Jo, Suwon-si (KR); Minwoo Lee, Suwon-si (KR); Joonho Jun, Suwon-si (KR); Duk Sung Kim, Suwon-si (KR)

(21) Appl. No.: 18/967,362

(22) Filed: Dec. 3, 2024

(30) Foreign Application Priority Data
Apr. 19, 2024 (KR) 10-2024-0052664

(51) Int. Cl. G11C 11/406; G11C 11/4091; G11C 11/4096

(52) U.S. Cl. CPC G11C 11/40615; G11C 11/4091; G11C 11/4096

(57) ABSTRACT

An example memory device includes a memory cell connected with a bit line, an equalization circuit connected with the bit line and a complementary bit line, a data sensing circuit connected with at least one of the bit line or the complementary bit line, where the data sensing circuit is configured to sense data in the memory cell and to output a data sense signal, a sense amplification circuit connected with the bit line and the complementary bit line, where the sense amplification circuit is configured to perform a refresh operation on the memory cell, and a refresh control circuit configured to receive the data sense signal and to control the refresh operation of the sense amplification circuit. Based on the data of the memory cell being “0”, the refresh control circuit is configured to output a first control signal such that the sense amplification circuit skips the refresh operation.

### CROSS-REFERENCE TO RELATED APPLICATION

This application claims priority to Korean Patent Application No. 10-2024-0052664, filed in the Korean Intellectual Property Office on Apr. 19, 2024, the entire contents of which are hereby incorporated by reference.

### BACKGROUND

Memory devices may be largely classified into volatile memory devices and nonvolatile memory devices. The volatile memory devices are memory devices in which stored data is lost when power supply is cut off. The volatile memory devices, and especially the dynamic random access memory (DRAM) is used in various fields such as mobile systems, servers, and graphics devices.

In the volatile memory device like the dynamic random access memory, a cell charge stored in a memory cell may be lost due to a leakage current. Additionally, if the word line frequently transitions between the active and precharge states, that is, if the word line is accessed intensively, it affects memory cells connected to adjacent word lines, resulting in the loss of cell charges stored in memory cells connected to the adjacent word lines. The charge in the memory cell should be recharged before the cell charge is lost and the data is completely corrupted. This recharging of the cell charge may be referred to as refresh operation. When the refresh operation is performed repeatedly before the cell charge is lost, power is significantly consumed.

### SUMMARY

In some implementations, a memory device may include a memory cell connected with a bit line, an equalization circuit connected with the bit line and a complementary bit line, a data sensing circuit connected with at least one of the bit line or the complementary bit line, wherein the data sensing circuit is configured to sense data in the memory cell and to output a data sense signal, a sense amplification circuit connected with the bit line and the complementary bit line, wherein the sense amplification circuit is configured to perform a refresh operation on the memory cell, and a refresh control circuit configured to receive the data sense signal and to control the refresh operation of the sense amplification circuit, wherein the refresh control circuit is configured to, based on the data of the memory cell being “0”, output a first control signal that enables the sense amplification circuit to skip the refresh operation.

In some implementations, a memory device may include a memory cell connected with a bit line, a data sensing circuit connected with at least one of the bit line or a complementary bit line, wherein the data sensing circuit is configured to sense data in the memory cell and to output a data sense signal, and a refresh control circuit configured to receive the data sense signal and control a refresh operation of a sense amplification circuit, wherein the refresh control circuit is configured to, based on the data of the memory cell being “0”, output a first control signal that enables the sense amplification circuit to skip the refresh operation.

In some implementations, a memory device may include a memory cell array including a plurality of memory cells, a row decoder connected with the memory cell array through a plurality of word lines, wherein the row decoder is configured to select a word line corresponding to an address signal and to control the selected word line, a column decoder connected with the memory cell array through a plurality of bit lines, wherein the column decoder is configured to select a bit line corresponding to the address signal, a sense amplifier configured to sense a voltage of the selected bit line and to control the voltage of the selected bit line, an input and output circuit configured to transmit and receive data with the sense amplifier, and a refresh control circuit configured to control a refresh operation performed by the sense amplifier, wherein the sense amplifier includes a plurality of bit line sense amplifiers connected with the memory cell array through the plurality of bit lines, wherein each of the plurality of bit line sense amplifiers includes an equalization circuit connected with a bit line and a complementary bit line, a data sensing circuit connected with at least one of the bit line or the complementary bit line, wherein the data sensing circuit is configured to sense data in the memory cell and to output a data sense signal, and a sense amplification circuit connected with the bit line and the complementary bit line, wherein the sense amplification circuit is configured to perform the refresh operation on the memory cell, and wherein the refresh control circuit is configured to receive the data sense signal and based on the data of the memory cell being “0”, output a first control signal that enables the sense amplification circuit to skip the refresh operation.

According to some aspects of the present disclosure, power consumption can be reduced by skipping the refresh operation if the data stored in the memory cell is “0” and performing the refresh operation only if the data stored in the memory cell is “1”.

The various and beneficial advantages and effects of the present disclosure are not limited to the above description, and can be more easily understood in the course of describing a specific aspect of the present disclosure.

### BRIEF DESCRIPTION OF THE DRAWINGS

FIG. 1 is a schematic block diagram illustrating an example of a memory device.

FIGS. 2 and 3 are schematic diagrams illustrating a structure of an example of a memory device.

FIG. 4 is a diagram illustrating an example of a configuration of the bit line sense amplifier.

FIG. 5 is a flowchart illustrating an example of a method for determining whether to perform the refresh operation.

FIG. 6 is a diagram illustrating an example of the memory device including the memory cell and the bit line sense amplifier.

FIG. 7 is a diagram illustrating an example of the equalization circuit.

FIG. 8 is a diagram illustrating an example of the data sensing circuit.

FIGS. 9 and 10 are diagrams illustrating examples of refresh control circuits.

FIG. 11 is a diagram illustrating an example of the sense amplification circuit.

FIG. 12 is a diagram illustrating an example of a logic state of a signal for each operation period of the refresh process.

FIG. 13 is a diagram illustrating an example in which the refresh operation is performed in the first refresh mode and the second refresh mode.

FIG. 14 is a diagram provided to explain an example in which the refresh operation is skipped when the data stored in the memory cell is “0” in the second refresh mode.

### DETAILED DESCRIPTION

Hereinafter, aspects of the present disclosure will be described as follows with reference to the accompanying drawings.

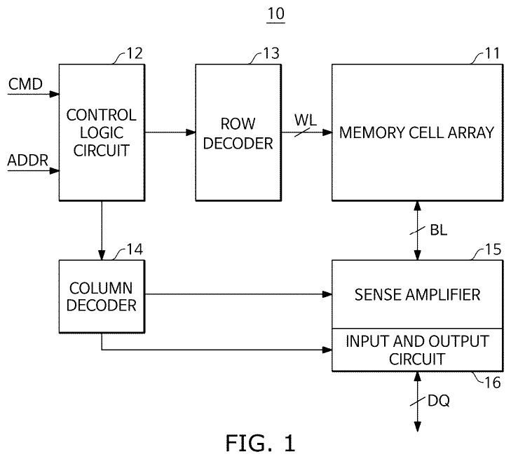

FIG. 1 is a schematic block diagram illustrating an example of a memory device 10.

Referring to FIG. 1, the memory device 10 may be a storage device based on a semiconductor device. The memory device 10 may be a random access memory (RAM) device, such as dynamic random access memory (DRAM), synchronous DRAM (SDRAM), static RAM (SRAM), double date rate SDRAM (DDR SDRAM), DDR2 SDRAM, DDR3 SDRAM, phase-change RAM (PRAM), magnetic RAM (MRAM), resistive RAM (RRAM), etc. The memory device 10 may be a memory device implemented based on the high bandwidth memory (HBM) standard. For example, the memory device 10 may be the memory device 10 included in a stacked memory device implemented based on the HBM standard. Additionally or alternatively, the memory device 10 may be the memory device 10 included in a semiconductor system including a chiplet. In response to an address signal ADDR and a control command signal CMD received from an external host (e.g., a central processing unit (CPU), an application processor (AP), a system-on-chip (SoC)), the memory device 10 may store data received through data signal DQ, or output data based on the data signal DQ.

The memory device 10 may include a memory cell array 11, a control logic circuit 12, a row decoder 13, a column decoder 14, a sense amplifier 15, an input and output circuit 16, etc.

The memory cell array 11 may include a plurality of memory cells, and the plurality of memory cells may be connected to the row decoder 13 and the sense amplifier 15 through a plurality of word lines WL and a plurality of bit lines BL.

Each of the plurality of memory cells may be positioned at a point where the plurality of word lines WL and the plurality of bit lines BL intersect. The plurality of memory cells may be arranged in a matrix form in the memory cell array 11, and each of the plurality of memory cells may include at least one memory element for storing data. For example, if the memory device 10 is the dynamic random access memory (DRAM), each of the plurality of memory cells may include a switch element (e.g., a transistor) and a cell capacitor.

The control logic circuit 12 may receive an address signal ADDR and a control command signal CMD from an external host. The address signal ADDR may include a row address indicating a row in the memory cell array 11 and a column address indicating a column in the memory cell array 11. For example, the row decoder 13 may refer to the address signal (e.g., the row address) to select at least one of the plurality of word lines WLs corresponding to the address signal, and the column decoder 14 may refer to the address signal (e.g., the column address) to select at least one of the plurality of bit lines BLs corresponding to the address signal.

The sense amplifier 15 may include a plurality of bit line sense amplifiers (BLSA) connected to the memory cell array 11 through a plurality of bit lines. A bit line sense amplifier of the plurality of bit line sense amplifiers, which is connected to a select bit line selected by the column decoder 14, may read the data stored in at least one of the memory cells connected to the selection bit line. The input and output circuit 16 may output, in the data signal DQ, the data read by the bit line sense amplifier. To this end, the input and output circuit 16 may transmit and receive data with the sense amplifier 15. Additionally or alternatively, the sense amplifier 15 may sense and control the voltage of the selected bit line. For example, the sense amplifier 15 (or the bit line sense amplifier) may perform the refresh operation of re-storing data stored in at least one of the memory cells connected to the bit line.

The memory device 10 may further include a refresh control circuit. The refresh control circuit may control the refresh operation performed by the sense amplifier (or the bit line sense amplifier). The refresh control circuit may be disposed in a conjunction region, but is not limited thereto. The conjunction area may be an area disposed adjacent to an area in which a sub-word line driver is disposed and an area in which the bit line sense amplifier is disposed.

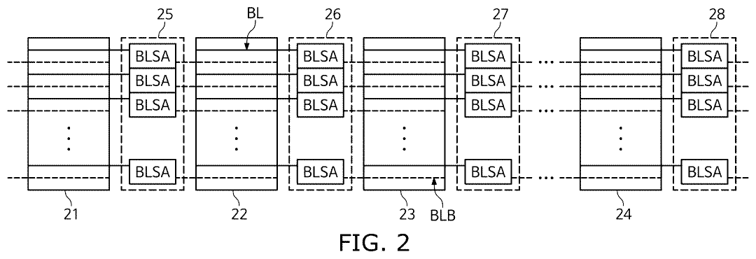

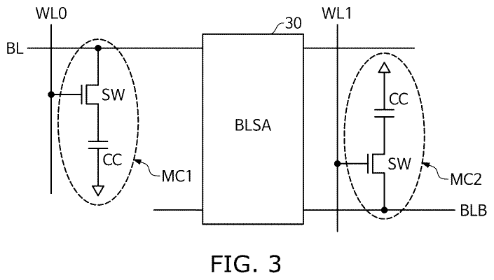

FIGS. 2 and 3 are schematic diagrams illustrating a structure of an example of a memory device.

First, referring to FIG. 2, the memory device may include a plurality of sub-arrays 21, 22, 23, and 24 in which memory cells are disposed, respectively, and a plurality of sense amplifiers 25, 26, 27, and 28. Each of the plurality of sense amplifiers 25, 26, 27, and 28 may include a plurality of bit line sense amplifiers BLSA.

As illustrated in FIG. 2, in each of the plurality of sub-arrays 21, 22, 23, and 24, the memory cell may be connected to at least one of a bit line BL and a complementary bit line BLB, and each of the plurality of bit line sense amplifiers BLSA may be connected to one of the bit lines BL and one of the complementary bit lines BLB. Accordingly, each of the plurality of bit line sense amplifiers BLSA may be connected to the memory cell in an open bit line manner.

Referring to FIG. 3, one bit line sense amplifier 30 may be connected to the bit line BL and the complementary bit line BLB. In addition, one bit line sense amplifier 30 may be connected to a first memory cell MC1 through the bit line BL and connected to a second memory cell MC2 through the complementary bit line BLB. Each of the first memory cell MC1 and the second memory cell MC2 may include a switch element SW and a cell capacitor CC. The first memory cell MC1 and the second memory cell MC2 may be the memory cells arranged in different sub-arrays 21, 22, 23, and 24 of FIG. 2. In addition, the first memory cell MC1 and the second memory cell MC2 may be the memory cells connected to word lines WL0 and WL1 different from each other. The bit line sense amplifier 30 may perform the refresh operation on the first memory cell MC1 and/or the second memory cell MC2 connected to the bit line sense amplifier 30.

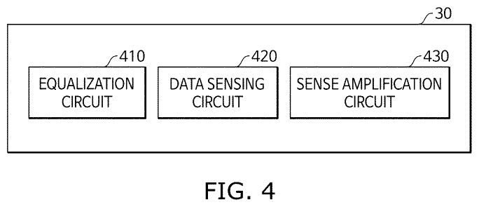

FIG. 4 is a diagram illustrating an example of a configuration of the bit line sense amplifier 30. Referring to FIG. 4, the bit line sense amplifier 30 may include an equalization circuit 410, a data sensing circuit 420, and a sense amplification circuit 430.

The equalization circuit 410 may be connected to a bit line and a complementary bit line. The equalization circuit 410 may charge a bit line voltage and a complementary bit line voltage to a precharge voltage based on an equalization control signal, and maintain the bit line voltage and the complementary bit line voltage at the precharge voltage. For example, the bit line and the complementary bit line may be charged to the precharge voltage by the equalization circuit 410 before the capacitor of the memory cell is connected to the bit line.

The data sensing circuit 420 may be connected to at least one of the bit line and the complementary bit line. Based on an operation signal, the data sensing circuit 420 may sense data stored in the memory cell connected to the bit line and output a data sense signal. For example, the data sensing circuit 420 may be configured to sense the data in the memory cell after the capacitor of the memory cell is connected to the bit line.

The sense amplification circuit 430 may be connected to the bit line and the complementary bit line. The sense amplification circuit 430 may amplify a voltage difference between the bit line and the complementary bit line based on the first and the second power voltages. The refresh operation of re-storing the data stored in the memory cell connected to the bit line may be performed by the amplification by the sense amplification circuit 430.

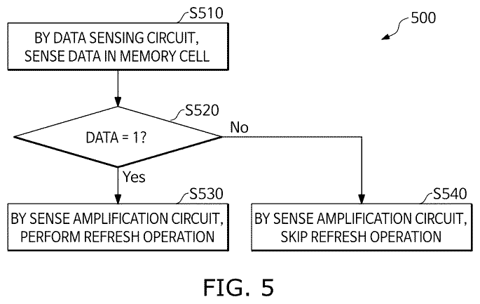

FIG. 5 is a flowchart illustrating an example of a method 500 for determining whether to perform the refresh operation. Referring to FIG. 5, first, the data sensing circuit may sense the data stored in the memory cell, at S510. The data sensing by the data sensing circuit may be performed while the refresh operation (i.e., amplification operation) by the sense amplification circuit is performed. The refresh control circuit may receive the data sense signal sensed by the data sensing circuit.

The refresh control circuit may determine, based on the data sense signal, whether the data stored in the memory cell is “1” or “0”, at S520. If it is determined that the data stored in the memory cell is “1”, the sense amplification circuit may continue to perform the refresh operation, at S530. For example, the sense amplification circuit may perform the amplification operation for a predetermined time or longer than a predetermined threshold time. If it is determined that the data of the memory cell is “0”, the refresh operation by the sense amplification circuit may be skipped (or stopped), at S540.

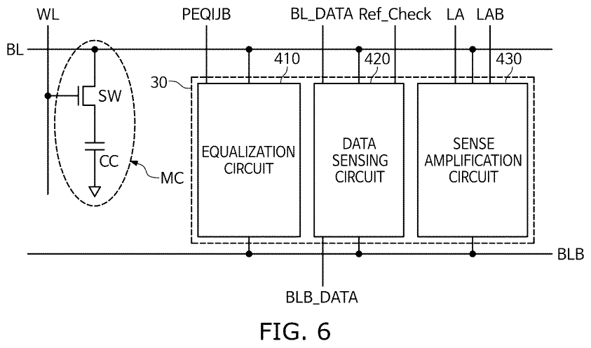

FIG. 6 is a diagram illustrating an example of the memory device including the memory cell MC and the bit line sense amplifier 30.

The memory cell MC may be connected to the bit line BL and the word line WL. The memory cell MC may include a switch element SW and a cell capacitor CC.

The switch element SW of the memory cell MC may be turned ON in response to the word line WL connected to the memory cell MC being activated. That is, in response to the word line WL being activated, the bit line BL and the cell capacitor CC may be electrically connected. In addition, the switch element SW of the memory cell MC may be turned OFF if the word line WL connected to the memory cell MC is deactivated. That is, if the word line WL is deactivated, the electrical connection between the bit line BL and the cell capacitor CC may be disconnected.

The cell capacitor CC may have been charged to an amount of charge corresponding to the data stored in the memory cell. The amount of charge charged in the cell capacitor CC may be changed (e.g., decreased) due to various causes such as leakage current. Accordingly, the memory device may perform the refresh operation to preserve data stored in the memory cell MC.

The bit line sense amplifier 30 may perform the refresh operation. The bit line sense amplifier 30 may include the equalization circuit 410, the data sensing circuit 420, and the sense amplification circuit 430.

The equalization circuit 410 may be connected to the bit line BL and the complementary bit line BLB. Based on the equalization control signal PEQIJB being activated, the equalization circuit 410 may charge a voltage of the bit line BL and a voltage of the complementary bit line BLB to a precharge voltage V_{BL}(e.g., V_{BL}=p*V_{DD}(0<p<1), specifically, VBL=0.5 V_{DD}), and maintain the voltages of the bit line BL and the complementary bit line at the precharge voltage V_{BL}.

After the bit line BL and the complementary bit line BLB are precharged by the equalization circuit 410, if the equalization control signal PEQIJB is deactivated and the word line WL is activated, the voltage of the bit line BL may change according to charge sharing between the bit line BL and the cell capacitor CC. The word line WL may be activated after the equalization control signal PEQIJB is deactivated. For example, if the data stored in the memory cell MC is “1”, the voltage of the bit line BL may increase as the charge moves from the cell capacitor CC to the bit line BL. As another example, if the data stored in the memory cell MC is “O”, the voltage of the bit line BL may decrease as the charge moves from the bit line BL to the cell capacitor CC. As a result, a difference may occur between the voltage of the bit line BL and the voltage of the complementary bit line BLB.

The sense amplification circuit 430 may be connected to the bit line BL and the complementary bit line BLB. The sense amplification circuit 430 may amplify the voltage difference between the bit line BL and the complementary bit line BLB based on a first power voltage LA and a second power voltage LAB. For example, if the voltage of the bit line BL is greater than the voltage of the complementary bit line BLB, the sense amplification circuit 430 may change the voltage of the bit line BL to a high level (e.g., V_{DD}) and change the voltage of the complementary bit line BLB to a low level (e.g., V_{GRND}). As another example, if the voltage of the bit line BL is less than the voltage of the complementary bit line BLB, the sense amplification circuit 430 may change the voltage of the bit line BL to a low level and change the voltage of the complementary bit line BLB to a high level. As described above, the logic levels of the bit line BL and the complementary bit line BLB may be in a complementary relationship by the amplification by the sense amplification circuit 430.

The length of time of performance of the amplification operation by the sense amplification circuit 430 may be determined based on the refresh mode and the data stored in the memory cell MC. For example, if it is a first refresh mode (e.g., if the operation signal Ref_Check is OFF), or if the data stored in the memory cell MC in a second refresh mode (e.g., the operation signal Ref_Check ON) is “1”, the sense amplification circuit 430 may perform the operation of amplifying the voltage difference between the bit line BL and the complementary bit line BLB longer than a first predetermined threshold time period. Additionally or alternatively, if the data stored in the memory cell MC in the second refresh mode is “0”, the operation of amplifying the voltage difference between the bit line BL and the complementary bit line BLB may be performed for a time period shorter than the second predetermined threshold time period, and may be stopped as the equalization circuit 410 performs the precharge operation upon activation of the equalization control signal PEQIJB.

The data sensing circuit 420 may be connected to at least one of the bit line BL and the complementary bit line BLB. Based on the activation of the operation signal Ref_Check, the data sensing circuit 420 may sense the data stored in the memory cell MC connected to the bit line BL and output a data sense signal (at least one of BL_DATA and BLB_DATA). The data sensing by the data sensing circuit 420 may be performed while the operation of amplifying the voltage difference between the bit line BL and the complementary bit line BLB is performed by the sense amplification circuit 430.

The data sensing by the data sensing circuit 420 may be performed in response to the voltage of at least one of the bit line BL or the complementary bit line BLB falling within a predetermined range by the amplification by the sense amplification circuit 430. For example, the data sensing by the data sensing circuit 420 may be activated when the voltage of at least one of the bit line BL or the complementary bit line BLB is equal to or greater than a predetermined ratio of the high level voltage.

The data sensing circuit 420 may sense the voltage of the bit line BL connected to the memory cell MC to sense the data stored in the memory cell MC. Additionally or alternatively, the data sensing circuit 420 may sense the voltage of the complementary bit line BLB, which is in the complementary relationship with the voltage of the bit line BL connected to the memory cell MC, to sense the data stored in the memory cell MC.

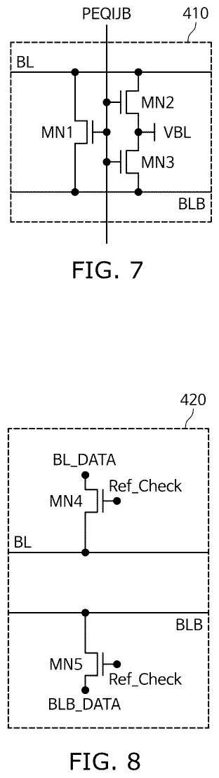

FIG. 7 is a diagram illustrating an example of the equalization circuit 410. Based on the equalization control signal PEQIJB, the equalization circuit 410 may charge the voltage of the bit line BL and the voltage of the complementary bit line BLB to the precharge voltage V_{BL} and maintain the same. An operation of the equalization circuit 410 of charging the voltage of the bit line BL and the voltage of the complementary bit line BLB to the precharge voltage V_{BL} and maintaining the same may be referred to as a precharge operation.

The equalization circuit 410 may be implemented to include one or more transistors connected between the bit line BL and the complementary bit line BLB. For example, as illustrated in FIG. 7, the equalization circuit 410 may be implemented to include a first NMOS transistor MN1 connected between the bit line BL and the complementary bit line BLB, a second NMOS transistor MN2 and a third NMOS transistor MN3 connected in series between the bit line BL and the complementary bit line BLB. A node between the second NMOS transistor MN2 and the third NMOS transistor MN3 connected in series may be maintained at the precharge voltage V_{BL}. If the equalization control signal PEQIJB is activated, channels are formed in the NMOS transistors MN1, MN2, and MN3 included in the equalization circuit 410, so that the bit line BL and the complementary bit line BLB may be electrically connected to the node maintained at the precharge voltage V_{BL} between the second NMOS transistor MN2 and the third NMOS transistor MN3. Accordingly, the voltage of the bit line BL and the voltage of the complementary bit line BLB may be charged to the precharge voltage V_{BL}. In addition, the voltage of the bit line BL and the voltage of the complementary bit line BLB may be maintained while the equalization control signal PEQIJB is active.

The configuration of the equalization circuit 410 is not limited to the example illustrated in FIG. 7, and may be configured with any circuit capable of charging and maintaining the voltage of the bit line BL and the voltage of the complementary bit line BLB to the precharge voltage V_{BL}.

FIG. 8 is a diagram illustrating an example of the data sensing circuit 420. Based on the operation signal Ref_Check, the data sensing circuit 420 may sense the data stored in the memory cell connected to the bit line BL and output a data sense signal (at least one of BL_DATA and BLB_DATA).

The data sensing circuit 420 may be implemented to include at least one of a transistor connected to the bit line BL or a transistor connected to the complementary bit line BLB. For example, the data sensing circuit 420 may include at least one of a fourth NMOS transistor MN4 connected to the bit line BL or a fifth NMOS transistor MN5 connected to the complementary bit line BLB. If the operation signal Ref_Check is activated, a channel is formed in the NMOS transistor (at least one of MN4 and MN5) included in the data sensing circuit 420, so that the first data sense signal BL_DATA may output the voltage of the bit line BL and/or the second data sense signal BLB_DATA may output the voltage of the complementary bit line BLB. Accordingly, the data stored in the memory cell connected to the bit line BL may be sensed, and the first data sense signal and/or the second data sense signal may be output.

The first data sense signal BL_DATA outputting the voltage of the bit line BL may indicate bit line data, that is, the data stored in the memory cell. The second data sense signal BLB_DATA outputting the voltage of the complementary bit line BLB in the complementary relationship with the bit line BL may indicate complementary bit line data, that is, inverted data of the data stored in the memory cell.

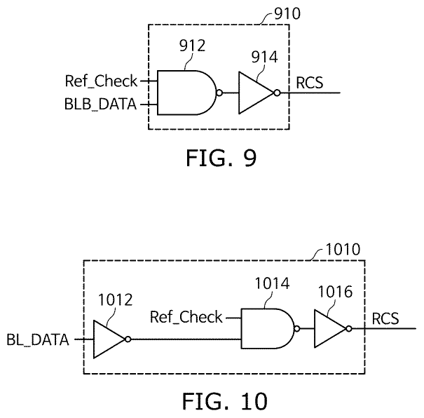

FIGS. 9 and 10 are diagrams illustrating examples of refresh control circuits 910 and 1010. The refresh control circuits 910 and 1010 may receive the data sense signals BL_DATA and BLB_DATA output by the data sensing circuit. Based on the data sense signals BL_DATA and BLB_DATA, the refresh control circuits 910 and 1010 may output a control signal RCS indicating whether the sense amplification circuit is to perform the refresh operation (i.e., an amplification operation) or skip the same. For example, if the data sense signals BL_DATA and BLB_DATA indicate that the data stored in the memory cell is “0”, the refresh control circuits 910 and 1010 may output a first control signal (e.g., a high level signal) such that the sense amplification circuit skips the refresh operation.

If the first control signal is output, the word line associated with the memory cell may be deactivated in response to the first control signal, and the equalization control signal may be activated to perform the precharge operation. As a result, the amplification operation by the sense amplification circuit may be performed for a time period shorter than a predetermined time period (e.g., a first predetermined threshold time period). In this case, the first predetermined threshold time period may be a time period shorter than a time period sufficient to perform the refresh operation. As another example, if the data sense signals BL_DATA and BLB_DATA indicate that data stored in the memory cell is “1”, the refresh control circuits 910 and 1010 may output a second control signal such that the sense amplification circuit performs the refresh operation. If the second control signal is output, the amplification operation by the sense amplification circuit may be performed longer than a predetermined time period (e.g., a second predetermined threshold time period). The second predetermined threshold time period may be a time period equal to or longer than a time period sufficient to perform the refresh operation. In addition, the first predetermined threshold time period may be a time period shorter than the second predetermined threshold time period.

The refresh control circuits 910 and 1010 may further receive the operation signal indicating the type of the refresh mode. In this case, the refresh control circuits 910 and 1010 may output the control signal RCS based on the operation signal and the data sense signals BL_DATA and BLB_DATA. For example, if the operation signal is in a first logic state (e.g., a high level signal) indicating the second refresh mode (e.g., a sparsity refresh mode) and the data sense signals BL_DATA and BLB_DATA indicate that the data stored in the memory cell is “0”, the refresh control circuits 910 and 1010 may output the first control signal such that the sense amplification circuit skips the refresh operation. Alternatively, if the operation signal is in the first logic state indicating the second refresh mode and the data sense signals BL_DATA and BLB_DATA indicate that the data stored in the memory cell is “1”, the refresh control circuits 910 and 1010 may output the second control signal such that the sense amplification circuitry performs the refresh operation. As another example, if the operation signal is in the second logic state (e.g., a low level signal) indicating the first refresh mode (e.g., a normal refresh mode), the refresh control circuits 910 and 1010 and the data sensing circuit may be deactivated. In this case, the refresh operation of the sense amplification circuit may be performed both when the data of the memory cell is “0” and when it is “1”. That is, if the operation signal is in the second logic state indicating the second refresh mode, the refresh control circuits 910 and 1010 may output the second control signal such that the sense amplification circuit may perform the refresh operation regardless of the data sense signals BL_DATA and BLB_DATA.

The refresh control circuits 910 and 1010 may be implemented to include a logic gate. For example, as illustrated in FIG. 9, the refresh control circuit 910 may include a NAND circuit 912 that receives the second data sense signal BLB_DATA indicating the complementary bit line data and the operation signal Ref_Check and performs a NAND operation, and an inverter circuit 914 that inverts the output signal of the NAND circuit 912 to generate an inverted data signal. The inverted data signal generated by the inverter circuit 914 may be a control signal RCS that is an output of the refresh control circuit 910.

As another example, as illustrated in FIG. 10, the refresh control circuit 1010 may include a first inverter circuit 1012 that inverts the first data sense signal BL_DATA indicating the bit line data to generate a first inverted data signal, a NAND circuit 1014 that receives the operation signal Ref_Check and the first inverted data signal to perform a NAND operation, and a second inverter circuit 1016 that inverts the output signal of the NAND circuit 1014 to generate a second inverted data signal. The second inverted data signal generated by the second inverter circuit 1016 may be a control signal RCS that is an output of the refresh control circuit 1010.

In an example, one of the refresh control circuit 910 illustrated in FIG. 9 and the refresh control circuit 1010 illustrated in FIG. 10 may be used. In another example, the refresh control circuit 910 illustrated in FIG. 9 and the refresh control circuit 1010 illustrated in FIG. 10 may be used.

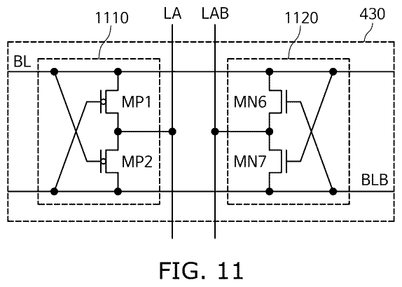

FIG. 11 is a diagram illustrating an example of the sense amplification circuit 430. The amplification operation by the sense amplification circuit 430 may be performed in a state in which there is a difference between the voltage on the bit line BL and the voltage on the complementary bit line BLB due to the deactivated equalization control signal and the activated word line. The sense amplification circuit 430 may amplify the voltage difference between the bit line BL and the complementary bit line BLB based on the first power voltage LA and the second power voltage LAB.

The sense amplification circuit 430 may include a P-type amplification circuit 1110 and an N-type amplification circuit 1120. The P-type amplification circuit 1110 and the N-type amplification circuit 1120 may amplify the voltage difference between the bit line BL and the complementary bit line BLB based on the first power voltage LA and the second power voltage LAB, respectively. For example, the P-type amplification circuit 1110 may be implemented to include a first PMOS transistor MP1 and a second PMOS transistor MP2 connected in series between the bit line BL and the complementary bit line BLB. The N-type amplification circuit 1120 may be implemented to include a sixth NMOS transistor MN6 and a seventh NMOS transistor MN7 connected in series between the bit line BL and the complementary bit line BLB. A node between the first PMOS transistor MP1 and the second PMOS transistor MP2 connected in series may be provided with the first power voltage LA, and a node between the sixth NMOS transistor MN6 and the seventh NMOS transistor MN7 connected in series may be provided with the second power voltage LAB.

If the voltage of the bit line BL is greater than the voltage of the complementary bit line BLB, the sense amplification circuit 430 may change the voltage of the bit line BL to a high level (e.g., V_{DD}) and change the voltage of the complementary bit line BLB to a low level (e.g., V_{GRND}). For example, in the implementation of FIG. 11, if the voltage of the bit line BL is greater than the precharge voltage, a channel is formed in the seventh NMOS transistor MN7 such that the second power voltage LAB and the complementary bit line BLB may be electrically connected. In this state, the second power voltage LAB may provide the low level voltage (e.g., V_{GRND}), and as a result, the complementary bit line BLB may be changed to the low level. According to the complementary bit line BLB changed to the low level, a channel may be formed in the first PMOS transistor MP1, electrically connecting the first power voltage LA and the bit line BL to each other. In this state, the first power voltage LA may provide the high level voltage (e.g., V_{DD}), and as a result, the bit line BL may be changed to the high level.

As another example, if the voltage of the bit line BL is less than the voltage of the complementary bit line BLB, the sense amplification circuit 430 may change the voltage of the bit line BL to the low level and change the voltage of the complementary bit line BLB to the high level. For example, in the implementation example of FIG. 11, if the voltage of the bit line BL is less than the precharge voltage, a channel may be formed in the second PMOS transistor MP2, electrically connecting the first power voltage LA and the complementary bit line BLB. In this state, the first power voltage LA may provide the high level voltage, and as a result, the complementary bit line BLB may be changed to the high level. According to the complementary bit line BLB changed to the high level, a channel may be formed in the first NMOS transistor MN6, electrically connecting the first power voltage LAB and the bit line BL to each other. In this state, the second power voltage LAB may provide the low level voltage, and as a result, the bit line BL may be changed to the low level.

If the word line is activated and the equalization control signal is activated, the amplification operation of the voltage difference by the sense amplification circuit 430 may be stopped.

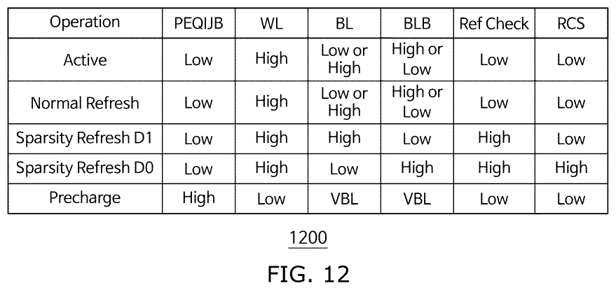

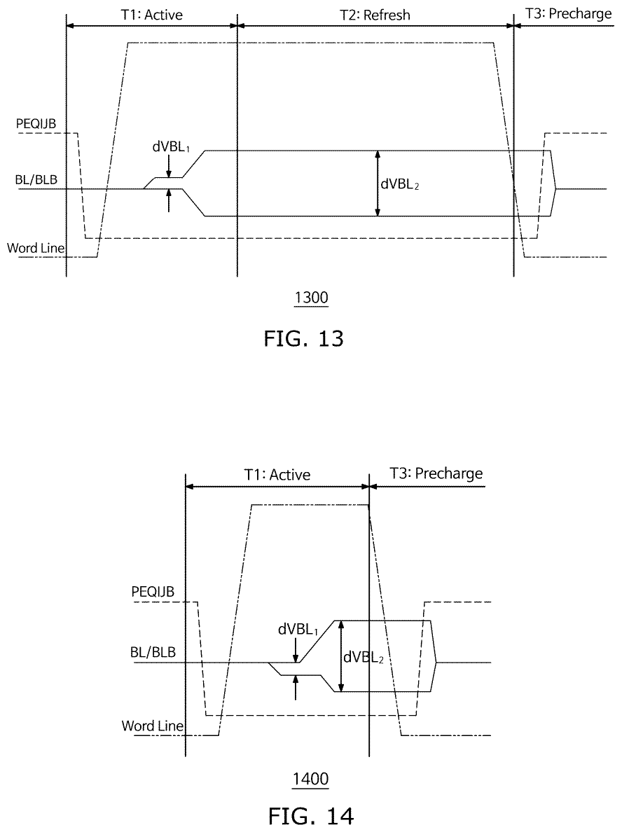

FIG. 12 is a diagram illustrating an example 1200 of a logic state of a signal for each operation period of the refresh process. FIG. 13 is a diagram illustrating an example 1300 in which the refresh operation is performed in the first refresh mode and the second refresh mode. FIG. 14 is a diagram provided to explain an example 1400 in which the refresh operation is skipped when the data stored in the memory cell is “0” in the second refresh mode.

Referring to FIGS. 12 and 13, if the data stored in the memory cell in the first refresh mode (normal refresh mode) is “1”, an active period T1 (corresponding to when BL is the high level and BLB is the low level in Active of FIG. 12), a refresh period T2 (Normal Refresh of FIG. 12), and a precharge period T3 (Precharge of FIG. 12) may follow.

In the active period T1, after the equalization control signal PEQIJB is transitioned (deactivated) from the high level to the low level, the word line WL may be transitioned (activated) from the low level to the high level. Accordingly, the bit line and the cell capacitor of the memory cell may be electrically connected to each other, resulting in the bit line voltage BL being increased due to the charge sharing phenomenon. As a result, a difference dVBL₁ may occur between the bit line voltage BL and the complementary bit line voltage BLB, and the sense amplification circuit may be operated. The sense amplification circuit may amplify the difference between the bit line voltage BL and the complementary bit line voltage BLB to a maximum voltage difference dVBL₂.

In the refresh period T2, the amplification operation by the sense amplification circuit may continue for a predetermined time or more. That is, the refresh operation may be performed. In this state, because the word line WL is activated and the bit line and the cell capacitor of the memory cell are electrically connected to each other, the amplified bit line voltage BL may be charged to the cell capacitor of the memory cell.

In the precharge period T3, after the word line WL is transitioned from the high level to the low level, the equalization control signal PEQIJB may be transitioned from the low level to the high level. Accordingly, the bit line voltage BL and the complementary bit line voltage BLB may be charged to the precharge voltage and maintained.

If the data stored in the memory cell is “0” in the first refresh mode, the same process as the process described above applies, except that the difference dVBL₁ occurs between the bit line voltage BL and the complementary bit line voltage BLB due to the decreased bit line voltage BL in the active period T1 (corresponding to when BL is the low level and BLB is the high level in Active in FIG. 12). In the first refresh mode, the operation signal Ref_Check and the control signal RCS of the data sensing circuit and the refresh control circuit may be maintained at a low level regardless of the data stored in the memory cell. That is, the data sensing circuit and the refresh circuit may be maintained in the inactive state, and the refresh operation may be performed regardless of the data stored in the memory cell.

If the data stored in the memory cell is “1” in the second refresh mode (sparsity refresh mode), it is similar to when the data stored in the memory cell is “1” in the first refresh mode, except that the operation signal Ref_Check of the data sensing circuit and the refresh control circuit is in the first logic state (in the high level or active state).

If the data stored in the memory cell is “1” in the second refresh mode, while the voltage difference between the bit line voltage BL and the complementary bit line voltage BLB is being amplified by the sense amplification circuit in the active period T1, the data sensing circuit may output a data sense signal indicating that the data stored in the memory cell is “1” based on the high level operation signal Ref_Check. In addition, based on the operation signal Ref_Check and the data sense signal, the refresh control circuit may output a low level control signal RCS (e.g., the second control signal) such that the sense amplification circuit performs the refresh operation. Accordingly, the refresh period T2 (Sparsity Refresh D1 in FIG. 12) may start.

Referring to FIGS. 12 and 14, if the data stored in the memory cell is “0” in the second refresh mode (Sparsity Refresh mode), the active period T1 (which may change to Sparsity Refresh DO, if the BL of Active in FIG. 12 is in the low level and BLB is in the high level) and the precharge period T3 (Precharge in FIG. 12) may follow.

In the active period T1, after the equalization control signal PEQIJB is transitioned from the high level to the low level, the word line WL may be transitioned from the low level to the high level. Accordingly, the bit line and the cell capacitor of the memory cell may be electrically connected to each other, resulting in the bit line voltage BL being decreased due to the charge sharing phenomenon. As a result, a difference dVBL₁ may occur between the bit line voltage BL and the complementary bit line voltage BLB, and the sense amplification circuit may be operated. The sense amplification circuit may amplify the difference between the bit line voltage BL and the complementary bit line voltage BLB to a maximum voltage difference dVBL₂. While the voltage difference between the bit line voltage BL and the complementary bit line voltage BLB is being amplified by the sense amplification circuit, based on the high level operation signal Ref_Check, the data sensing circuit may sense the data stored in the memory cell and output a data sense signal indicating that the data stored in the memory cell is “0”. In addition, based on the operation signal Ref_Check and the data sense signal, the refresh control circuit may output a high level control signal (RCS) (e.g., the first control signal) such that the sense amplification circuit skips the refresh operation. Accordingly, the refresh period T2 may be skipped and the precharge period T3 may immediately start.

In the precharge period T3, after the word line WL is transitioned from the high level to the low level, the equalization control signal PEQIJB may be transitioned from the low level to the high level. Accordingly, the bit line voltage BL and the complementary bit line voltage BLB may be charged to the precharge voltage and maintained.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A memory device comprising:
a memory cell connected with a bit line;
an equalization circuit connected with the bit line and a complementary bit line;
a data sensing circuit connected with at least one of the bit line or the complementary bit line, wherein the data sensing circuit is configured to sense data in the memory cell and to output a data sense signal;
a sense amplification circuit connected with the bit line and the complementary bit line, wherein the sense amplification circuit is configured to perform a refresh operation on the memory cell; and
a refresh control circuit configured to receive the data sense signal and to control the refresh operation of the sense amplification circuit,
wherein the refresh control circuit is configured to, based on the data of the memory cell being “0,” output a first control signal that enables the sense amplification circuit to skip the refresh operation.

2. The memory device according to claim 1, wherein the refresh control circuit is configured to, based on the data of the memory cell being “1,” output a second control signal that enables the sense amplification circuit to perform the refresh operation.

3. The memory device according to claim 1, wherein the first control signal is configured to deactivate a word line associated with the memory cell and activate an equalization control signal.

4. The memory device according to claim 3, wherein the equalization circuit is configured to charge the bit line and the complementary bit line to a precharge voltage based on the equalization control signal being activated.

5. The memory device according to claim 3, wherein the word line is deactivated after the sense amplification circuit performs an amplification operation for a time period shorter than a predetermined first threshold time period, the amplification operation amplifying a voltage difference between the bit line and the complementary bit line based on a first power voltage and a second power voltage.

6. The memory device according to claim 2, wherein the sense amplification circuit is configured to, based on the second control signal, perform an amplification operation for a time period longer than a predetermined second threshold time period, the amplification operation amplifying a voltage difference between the bit line and the complementary bit line based on a first power voltage and a second power voltage.

7. The memory device according to claim 1, wherein the data sensing circuit is configured to sense the data in the memory cell after a capacitor of the memory cell is connected with the bit line.

8. The memory device according to claim 7, wherein the data sensing circuit is configured to sense the data in the memory cell based on a voltage of at least one of the bit line or the complementary bit line falling within a predetermined range.

9. The memory device according to claim 7, wherein, before the capacitor of the memory cell is connected with the bit line, the bit line and the complementary bit line are charged to a precharge voltage by the equalization circuit.

10. The memory device according to claim 1, wherein the data sensing circuit and the refresh control circuit are configured to receive an operation signal, and
wherein the data sensing circuit and the refresh control circuit are configured to be activated based on the operation signal being in a first logic state, and
wherein the data sensing circuit and the refresh control circuit are configured to be deactivated based on the operation signal being in a second logic state.

11. The memory device according to claim 10, wherein the sense amplification circuit is configured to perform the refresh operation based on the operation signal being in the second logic state and further on the data of the memory cell being “0” or “1.”

12. The memory device according to claim 10, wherein the data sensing circuit is connected with the complementary bit line and is configured to output complementary bit line data in an active state, the complementary bit line data being inverted data of the data of the memory cell.

13. The memory device according to claim 12, wherein the refresh control circuit includes:
a NAND circuit configured to receive the operation signal and the complementary bit line data and to perform a NAND operation; and
an inverter configured to invert an output signal of the NAND circuit and to generate an inverted data signal,
wherein the inverted data signal generated by the inverter is an output of the refresh control circuit.

14. The memory device according to claim 10, wherein the data sensing circuit is connected with the bit line and is configured to output bit line data in an active state, the bit line data being the data of the memory cell.

15. The memory device according to claim 14, wherein the refresh control circuit includes:
a first inverter configured to invert the bit line data and to generate a first inverted data signal;
a NAND circuit configured to receive the operation signal and the first inverted data signal and to perform a NAND operation; and
a second inverter configured to invert the output signal of the NAND circuit and to generate a second inverted data signal,
wherein the second inverted data signal generated by the second inverter is an output of the refresh control circuit.

16. The memory device according to claim 1, wherein the memory device is a dynamic random access memory.

17. A memory device comprising:
a memory cell connected with a bit line;
a data sensing circuit connected with at least one of the bit line or a complementary bit line, wherein the data sensing circuit is configured to sense data in the memory cell and to output a data sense signal; and
a refresh control circuit configured to receive the data sense signal and to control a refresh operation of a sense amplification circuit,
wherein the refresh control circuit is configured to, based on the data of the memory cell being “0,” output a first control signal that enables the sense amplification circuit to skip the refresh operation.

18. The memory device according to claim 17, wherein the refresh control circuit is configured to, based on the data of the memory cell being “1,” output a second control signal that enables the sense amplification circuit to perform the refresh operation.

19. A memory device comprising:
a memory cell array including a plurality of memory cells;
a row decoder connected with the memory cell array through a plurality of word lines, wherein the row decoder is configured to select a word line corresponding to an address signal and to control the selected word line;
a column decoder connected with the memory cell array through a plurality of bit lines, wherein the column decoder is configured to select a bit line corresponding to the address signal;
a sense amplifier configured to sense a voltage of the selected bit line and to control the voltage of the selected bit line;
an input and output circuit configured to transmit and receive data with the sense amplifier; and
a refresh control circuit configured to control a refresh operation performed by the sense amplifier,
wherein the sense amplifier includes a plurality of bit line sense amplifiers connected with the memory cell array through the plurality of bit lines,
wherein each of the plurality of bit line sense amplifiers includes:
an equalization circuit connected with a bit line and a complementary bit line;
a data sensing circuit connected with at least one of the bit line or the complementary bit line, wherein the data sensing circuit is configured to sense data in the memory cell and to output a data sense signal; and
a sense amplification circuit connected with the bit line and the complementary bit line, wherein the sense amplification circuit is configured to perform the refresh operation on the memory cell, and
wherein the refresh control circuit is configured to receive the data sense signal and, based on the data of the memory cell being “0,” output a first control signal that enables the sense amplification circuit to skip the refresh operation.

20. The memory device according to claim 19, wherein the refresh control circuit is configured to, based on the data of the memory cell being “1,” output a second control signal that enables the sense amplification circuit to perform the refresh operation.
